(19) United States
(12) Patent Application Publication
(10) Pub. No.: US 2011/0150494 A1
(43) Pub. Date: Jun. 23, 2011

(54) OPTICAL TRANSCEIVER AND PACKAGING METHOD THEREOF

(75) Inventor: XIAO-YA GUO, Zhongshan City (CN)

(73) Assignees: AMBIT MICROSYSTEMS (ZHONGSHAN) LTD., Zhongshan City (CN); HON HAI PRECISION INDUSTRY CO., LTD., Tu-Cheng (TW)

(21) Appl. No.: 12/915,023

(22) Filed: Oct. 29, 2010

(30) Foreign Application Priority Data
Dec. 18, 2009 (CN) 200910189147.9

(51) Int. Cl. H04B 10/02; H05K 13/00

(52) U.S. Cl. 398/135; 29/592.1

(57) ABSTRACT

An optical transceiver includes a substrate, a positioning seat, a plurality of laser components, a bracket and a plurality of lenses. The positioning seat is installed on the substrate and includes a pair of positioning posts and a plurality of receiving holes between the positioning posts. The laser components pass through the receiving holes and are installed on the substrate. The bracket includes a top cover and one or more sidewalls. The one or more sidewalls surround the positioning seat and the plurality of laser components. The top cover defines a pair of positioning holes engaged with the pair of positioning posts to position the bracket corresponding to the positioning seat. The lenses are installed on the top cover of the bracket and correspond to the plurality of laser components on the substrate.

### BACKGROUND

1. Technical Field

The present disclosure generally relates to optical transceivers, and more particularly to a packaging method of an optical transceiver.

2. Description of Related Art

Optical communications has become increasingly popular and is widely used in information transmission. Generally, optical transceivers are used in optical communicating device to perform a conversion between electrical signals and optical signals. An optical transceiver comprises a plurality of laser components and a plurality of lenses. Definition of position between the laser components and the lenses effects performance of transmitting information of the optical transceiver. Therefore, how to make an exact definition of position between the laser components and the lenses is an important problem in study.

Therefore, a need exists in the industry to overcome the described limitations and reduce the size of the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of an optical transceiver of an exemplary embodiment of the disclosure.

FIG. 2 is a schematic view of installing a positioning seat onto a substrate of the optical transceiver of FIG. 1.

FIG. 3 is a schematic view of installing a plurality of laser components to the structure of FIG. 2.

FIG. 4 is a schematic view of installing a driving chip to the structure of FIG. 3.

FIG. 5 is an exploded schematic view of the optical transceiver of FIG. 1, showing a bracket and the structure of FIG. 4.

FIG. 6 is a schematic view of an optical transceiver of another embodiment of the disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

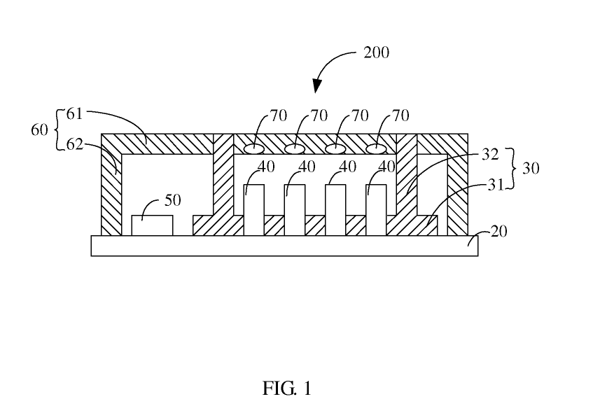

FIG. 1 is a schematic view of an optical transceiver 200 of an exemplary embodiment of the disclosure. The optical transceiver 200 is used to perform a conversion between an electrical signal and an optical signal and comprises a substrate 20, a positioning seat 30, a plurality of laser components 40, a bracket 60, and a plurality of lenses 70.

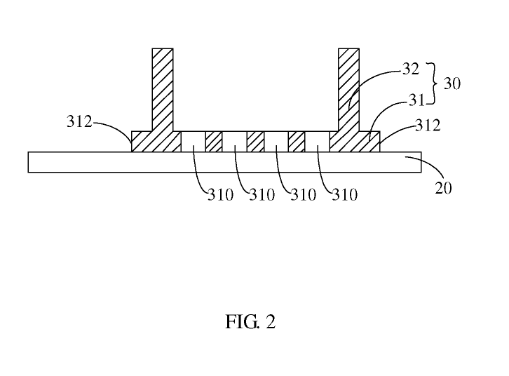

Referring to FIG. 2, the positioning seat 30 is installed on the substrate 20 and comprises a base 31 and a pair of positioning posts 32. The base 31 is affixed on the substrate 10 and defines a plurality of receiving holes 310. The pair of positioning posts 32 are respectively disposed on two opposite edges 312 of the base 31 and perpendicularly extend from the base 31. The plurality of receiving holes 310 are located between the pair of positioning posts 32.

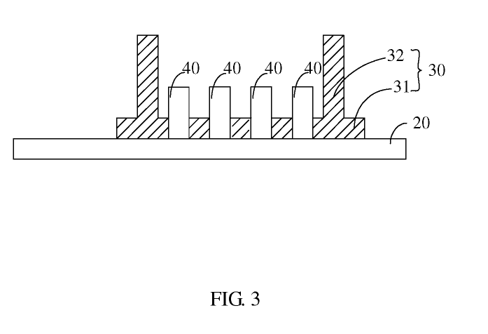

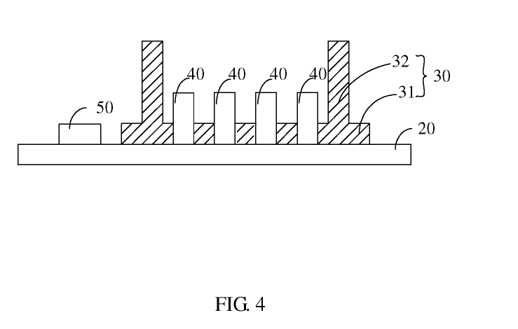

Referring to FIG. 3, the plurality of laser components 40 respectively pass through the plurality of receiving holes 310 and are installed on the substrate 20. In this embodiment, the optical transceiver 200 further comprises a driving chip 50 installed on the substrate 20 to drive the plurality of laser components 40 (shown in FIG. 4). The laser components 40 and the driving chip 50 are installed on the substrate 20 via welding process.

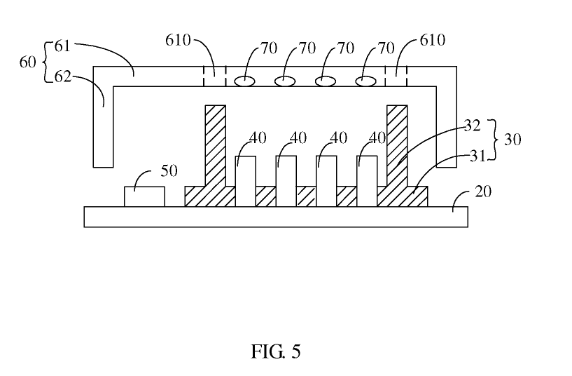

Referring to FIG. 5, the bracket 60 comprises a top cover 61 and one or more side walls 62 perpendicularly extending from the top cover 61 to the substrate 20. The one or more side walls 62 surround the positioning seat 30 and the plurality of laser components 40. The top cover 61 defines a pair of positioning holes 610 to engage with the pair of positioning posts 32 to position the bracket 60 to the positioning seat 30. The plurality of lenses 70 are installed on the top cover 61 of the bracket 60 via embedding during fabricating the bracket 60. The plurality of lenses 70 are located between the pair of positioning holes 610 and respectively accurately opposite to the plurality of laser components 40.

In this embodiment, the side walls 62 are affixed onto the substrate 20 to secure the bracket 60 to the substrate 20. The driving chip 50 and the positioning seat 30 are located between the pair of side walls 62.

In this embodiment, the pair of positioning posts 32 snugly engage with the pair of positioning holes 610, and the plurality of laser components 40 snugly engage with the plurality of receiving holes 310. The laser components 40 can be exactly positioned on the substrate 20 due to the engagement between the laser components 40 and the receiving holes 310 of the positioning seat 30. The bracket 60 can be positioned on the substrate 20 due to the engagement between the positioning posts 32 of the positioning seat 30 and the positioning holes 310. The positioning seat 30 acts as a common reference for positioning the laser components 40 and the bracket 60 to make a definition of position between the laser components 40 and the lenses 70.

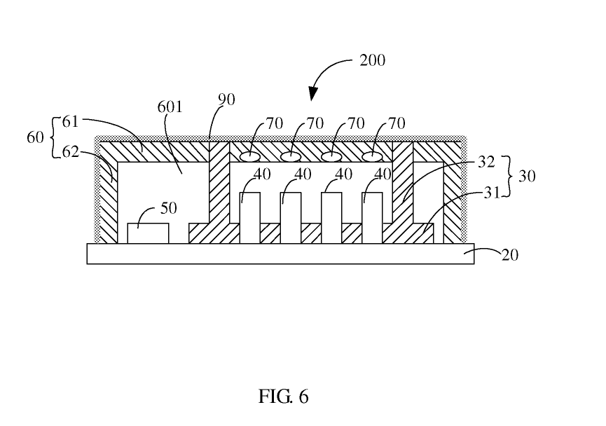

Referring FIG. 6, a schematic view of an optical transceiver of another embodiment of the disclosure is shown. The bracket 60, the substrate 20 and the positioning seat 30 cooperatively define an airtight space 601 to protect the laser components 40 and the driving chip 50 against humidity and dust. In this embodiment, the optical transceiver 200 further comprises a shielding layer 90 made of electromagnetic shield material and coated on the bracket 60 to shield electromagnetic interference from the laser components 40.

A method of making the optical transceiver 200 comprises steps as follow.

Provide the substrate 20.

Install the positioning seat 30 on the substrate 20. In this embodiment, the positioning seat 30 is affixed on the substrate 20.

Install the plurality of laser components 40 on the substrate 20. The plurality of laser components 40 respectively pass through the plurality of receiving holes 310 to be installed on the substrate 20 via welding process.

Fabricate the bracket 60 defining the pair of positioning holes 610 and comprising a plurality of lenses 70 embedded therein and located between the pair of positioning holes 610.

Install the bracket 60 to the substrate 20 via the pair of positioning holes 610 engaging with the pair of positioning posts 32. The bracket 60 surrounds the positioning seat 30 and the plurality of laser components 40.

In this embodiment, the method of making the optical transceiver 200 further comprises a step of installing the driving chip 50 on the substrate 20 after installing the plurality of laser components 40 on the substrate 20. The driving chip 50 is used to drive the plurality of laser components 40.

In this embodiment, the method of making the optical transceiver 200 further comprises coating the shielding layer 90 on the bracket 60 to shield electromagnetism interference from the laser components 40 after fabricating the bracket 60.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. An optical transceiver, comprising:
a substrate;
a positioning seat, installed on the substrate, comprising a base and a pair of positioning posts respectively disposed on two opposite edges of the base, the base defining a plurality of receiving holes between the pair of positioning posts;
a plurality of laser components, passing through the plurality of receiving holes and installed on the substrate, respectively;
a bracket, comprising a top cover and one or more sidewalls perpendicularly extending from the top cover to the substrate, wherein the one or more sidewalls surround the positioning seat and the plurality of laser components, the top cover defines a pair of positioning holes engaged with the pair of positioning posts to position the bracket corresponding to the positioning seat; and
a plurality of lenses, installed on the top cover of the bracket and corresponding to the plurality of laser components on the substrate.

2. The optical transceiver as claimed in claim 1, further comprising a driving chip installed on the substrate to drive the plurality of laser components.

3. The optical transceiver as claimed in claim 2, wherein the side walls are affixed onto the substrate, and the driving chip and the positioning seat are surrounded by the side walls.

4. The optical transceiver as claimed in claim 3, wherein the pair of positioning posts snugly match with the pair of positioning holes.

5. The optical transceiver as claimed in claim 4, wherein the plurality of laser components snugly match with the plurality of receiving holes.

6. The optical transceiver as claimed in claim 1, wherein the bracket, the substrate and the positioning seat cooperatively define an airtight space to protect the laser components and the driving chip against humidity and dust.

7. The optical transceiver as claimed in claim 6, further comprising a shielding layer coated on the bracket to shield electro-magnetic interference from the laser components.

8. A method of making an optical transceiver, comprising:
providing a substrate;
installing a positioning seat on the substrate, the positioning seat comprising a base and a pair of positioning posts respectively close to two opposite edges of the base, the base defining a plurality of receiving holes located between the pair of positioning posts;
installing a plurality of laser components on the substrate, the plurality of laser components respectively passing through the plurality of receiving holes;
fabricating a bracket, the bracket defining a pair of positioning holes and comprising a plurality of lenses embedded therein and located between the pair of positioning holes; and
installing the bracket to the substrate via the pair of positioning holes engaging with the pair of positioning posts, the bracket surrounding the positioning seat and the plurality of laser components, and the plurality of lenses respectively opposite to the plurality of laser components;

9. The method of making an optical transceiver as claimed in claim 8, further comprising installing a driving chip on the substrate after installing the plurality of laser components on the substrate, the driving chip used to drive the plurality of laser components.

10. The method of making an optical transceiver as claimed in claim 8, further comprising coating a shielding layer on the bracket to shield electromagnetic interference from the laser components after fabricating the bracket.
